(19) United States
(12) Patent Application Publication
(10) Pub. No.: US 2023/0172030 A1
(43) Pub. Date: Jun. 1, 2023

(54) DISPLAY APPARATUS

(71) Applicant: LG DISPLAY CO., LTD., Seoul (KR)

(72) Inventors: Dongjoo LEE, Gyeonggi-do (KR); Youngtaek HONG, Gangneung-si (KR)

(73) Assignee: LG DISPLAY CO., LTD., Seoul (KR)

(21) Appl. No.: 18/050,989

(22) Filed: Oct. 29, 2022

(30) Foreign Application Priority Data
Nov. 30, 2021 (KR) 10-2021-0169525

(51) Int. Cl. H10K 59/65; H10K 59/124

(52) U.S. Cl. CPC H01L 27/3234; H01L 27/3258; G09G 2330/04; G09G 3/3225

(57) ABSTRACT

A display apparatus includes a substrate including a display area, a camera hole, and a non-display area between the display area and the camera hole, a light-emitting element disposed in the display area, one or more cut-out parts and at least one dam disposed in the non-display area, a plurality of insulating films disposed on the substrate and disposed under the light-emitting element, the cut-out parts, and the dam, and a crack prevention structure disposed between the at least one dam and the camera hole.

### CROSS-REFERENCE TO RELATED APPLICATION

This application claims priority from Korean Patent Application No. 10-2021-0169525, filed on Nov. 30, 2021, which is hereby incorporated by reference in its entirety.

### BACKGROUND

### Field of the Disclosure

The present disclosure relates to a display apparatus, and more particularly, to a display apparatus in which a camera hole is disposed.

### Description of the Background

Recently, as the information age has arrived, displays visually expressing electrical information signals have been rapidly developed. In response to such a trend, various display apparatuses having excellent performance, such as a thin profile, a light weight, and low power consumption, have been developed.

Specific examples of such display apparatuses include a liquid crystal display (LCD) apparatus, an organic light-emitting diode (OLED) display apparatus, and a quantum dot display apparatus.

A display apparatus may include a display panel and a plurality of components for providing various functions. For example, in an existing display apparatus, cameras and various optical sensors are disposed at a peripheral portion of a display panel to perform various functions such as photographing, face recognition, and infrared distance measurement functions. However, through successive generations, so-called bezel-less or bezel-free designs, in which a screen is fully filled with a display area when a user looks at the display apparatus, have become more common, which makes it difficult to arrange such cameras and optical sensors. In order to achieve such a bezel-less or bezel-free design, research has been conducted on a method of moving cameras and optical sensors inside a display area of a display panel. As a result of the research, a technology called a hole-in display (HID) has been developed in which holes can be formed in a display panel to arrange cameras and optical sensors inside the holes in a display panel.

Although an HID has been described above in order to express that a hole is present in a display area, a hole-in active area (HiAA) may also be used in order to express that a hole is present inside an active area.

As an HID or an HiAA is developed and all cameras and sensors placed in the existing bezel area are moved to the inside of an active area of a display panel, extreme bezel-less or bezel-free designs can be applied.

A display area and an active area may be synonymously to describe an area in which a pixel is driven to emit light.

### SUMMARY

The present specification is directed to solving the above-described problems that may occur in designing a hole-in display (HID) or hole-in active area (HiAA) structure. Holes in which cameras or optical sensors are disposed may be formed in a display area or an active area. In this case, components such as a light-emitting element or a driving transistor required for a display may not be disposed in a hole area, and even a substrate of a display panel may be removed from the hole area. When the substrate of the display panel or the light-emitting element remains in the hole area, optical interference on cameras or sensors may occur, and thus, a function thereof may be degraded.

As described above, in order to remove the substrate of the display panel, a fine cutting process may be generally performed using a laser. When cutting is performed based on a phenomenon in which the substrate of the display panel is melted and broken by local thermal energy received from the laser, a large amount of energy may be accumulated in a local area of the substrate, and cracks may be generated due to the energy accumulated in the substrate at the time of a cutting process or after the cutting process.

Cracks generated in a cut portion of the substrate may expand or extend to a peripheral area due to stress generated as a subsequent process is performed. Specifically, the cracks generated in the cut portion of the substrate may expand or extend toward a display area, and in particular, the cracks may easily propagate in an inorganic insulating film disposed near the hole area.

Cracks generated in the cut portion of the substrate in the hole area, which may be regarded as the outside of the display area, may become a kind of moisture penetration path. Light-emitting elements disposed in the display area are provided with an organic material layer or an organic emission layer and thus have a vulnerable characteristic to moisture. Specifically, when moisture permeates into the organic material layer of the light-emitting element, an organic material reacts with the moisture to cause pixel shrinkage in which an emission area is gradually reduced or a dark spot phenomenon in which a pixel incompletely emits light. Accordingly, in order to prevent penetration of moisture due to cracks, a crack propagation prevention structure is disposed, thereby preventing the propagation of cracks generated in a cut portion of the hole area.

A main point of the present disclosure is that, in order to design a bezel-less or bezel-free display panel which is a development trend of display apparatuses, holes for arranging cameras and sensors in a display area are formed, and also, display quality is prevented from being degraded due to the holes.

In an aspect, aspects of the present disclosure may provide a display apparatus including a substrate including a display area, a camera hole, and a non-display area between the display area and the camera hole, a light-emitting element disposed in the display area, one or more cut-out parts and at least one dam disposed in the non-display area, a plurality of insulating films disposed on the substrate and disposed under the light-emitting element, the cut-out parts, and the dam, and a crack prevention structure disposed between the at least one dam and the camera hole.

In another aspect, aspects of the present disclosure may provide a display apparatus including a substrate including a non-display area disposed between a camera hole and a display area, a plurality of inorganic insulating films disposed in the display area and the non-display area, an organic light-emitting stack disposed on the plurality of inorganic insulating films to correspond to the display area, one or more cut-out parts and at least one dam disposed on the plurality of inorganic insulating films to correspond to the non-display area, and a crack prevention structure disposed in the one or more cut-out parts.

Other detailed matters of the aspects are included in the detailed description and the drawings.

In a display apparatus according to aspects of the present specification, a camera hole can be disposed inside a display area of a display panel, thereby providing a display apparatus in which an overall exterior of a display panel has a slim bezel or a narrow bezel.

Therefore, a user of a display apparatus can aesthetically use a device in which a front surface of a display apparatus is fully with a light-emitting screen, and by using a compact module that is functionally applied to a narrow bezel, a better sense of grip and a sense of light weight can be provided to the user.

In a display apparatus according to aspects of the present specification, a plurality of prevention parts are formed around a camera hole, thereby preventing penetration of moisture and oxygen flowing from the camera hole. The prevention part can block a movement path of moisture and oxygen by cutting off a connection of an organic common layer of a light-emitting element disposed on an entire surface of a display panel, that is, a light-emitting stack.

With reference to the straightness of an organic material in an organic material deposition process for forming a light-emitting stack, a vertical structure of a structure of a prevention part may be increased to form a long side portion, or a width of the side portion of the structure of the prevention part may be varied. An organic material is not stacked or is inevitably stacked non-uniformly on an area, which is not present in a deposition direction of the organic material through the side portion of the structure of the prevention part, or on the side portion perpendicular to the deposition direction. Thus, a material constituting the light-emitting stack may not be stacked or may be non-uniformly stacked on the side portion of the structure of the prevention part and thus structurally separated.

A plurality of dams are disposed near the prevention part, thereby preventing an organic insulating layer of an encapsulation layer from overflowing into a camera hole. Through the plurality of dams, it is possible to prevent contamination of a camera hole area and prevent interference on a camera to be disposed in the camera hole area that may occur when the organic insulating layer overflows to the camera hole.

Structures of a prevention part are disposed at a plurality of positions, thereby preventing penetration of moisture and oxygen from a camera hole, and the structures of the prevention part are formed in different shapes such as a positive tapered shape and a negative tapered shape to use the pros and cons of each structure, thereby obtaining more excellent effects of preventing moisture penetration and oxygen penetration.

The effects of the present specification are not limited to the above-described effects, and other effects not described above, will be apparent to a person having ordinary skill in the art from the following description.

It is to be understood that both the foregoing general description and the following detailed description are exemplary and explanatory and are intended to provide further explanation of the disclosure as claimed.

### BRIEF DESCRIPTION OF THE DRAWINGS

The above and other aspects, features and advantages of the present disclosure will be more apparent from the following detailed description taken in conjunction with the accompanying drawings, in which:

FIG. 1 is a view illustrating a front surface of a display panel according to an aspect of the present specification;

FIG. 2 is an enlarged plan view of area A of FIG. 1 which illustrates a display area;

FIG. 3 is a cross-sectional view along line I-I′ of FIG. 2 which illustrates a subpixel;

FIG. 4 is an enlarged plan view of area B of FIG. 1 which illustrates a camera hole;

FIG. 5 is an enlarged plan view of area C of FIG. 4 which illustrates a peripheral portion of the camera hole;

FIG. 6 is a cross-sectional view along line III-IV of FIG. 5 which illustrates a camera hole area;

FIG. 7 is cross-sectional views illustrating a crack prevention structure according to another aspect of the present disclosure;

FIG. 8 is cross-sectional views illustrating a crack prevention structure according to another aspect of the present disclosure;

FIG. 9 is cross-sectional views illustrating a crack prevention structure according to another aspect of the present disclosure;

FIG. 10 is cross-sectional views illustrating a crack prevention structure according to another aspect of the present disclosure;

FIG. 11 is cross-sectional views illustrating a crack prevention structure according to another aspect of the present disclosure;

FIG. 12 is cross-sectional views illustrating a crack prevention structure according to another aspect of the present disclosure;

FIG. 13 is cross-sectional views illustrating a crack prevention structure according to another aspect of the present disclosure;

FIG. 14 is cross-sectional views illustrating a crack prevention structure according to another aspect of the present disclosure; and

FIG. 15 is cross-sectional views illustrating a crack prevention structure according to another aspect of the present disclosure.

### DETAILED DESCRIPTION

The advantages and features of the present disclosure and methods for accomplishing the same will be more clearly understood from aspects to be described in detail below with reference to the accompanying drawings. However, the present disclosure is not limited to the following aspects but may be implemented in various different forms. The present aspects are provided only to complete the present disclosure and to fully provide the scope of the present disclosure to a person having ordinary skill in the art to which the present disclosure pertains, and the present disclosure will be defined by the appended claims.

Shapes, sizes, ratios, angles, and numbers disclosed in the drawings for describing the aspects of the present disclosure are merely an examples, and thus, the present disclosure is not limited to the illustrated details. Like reference numerals refer to like elements throughout. In describing the present disclosure, when the detailed description of the relevant known function or configuration is determined to unnecessarily obscure an important point of the present disclosure, the detailed description will be omitted. In a case where “comprise,” “have,” and “include” described in the present specification are used, another part may be added unless “only” is used. Any references to singular may include plural unless expressly stated otherwise.

In construing a component, the component is construed as including an error range even if there is no explicit description.

In describing a position relationship, for example, when a position relation between two parts is described as “on,” “over,” “under,” or “next,” one or more other parts may be “immediately” or “directly” is used.

In describing a time relationship, for example, when the temporal order is described as “after,” “subsequent,” “next,” or “before,” a case which is not continuous may be included unless “immediately” or “right” is used.

It should be understood that, although terms such as “first,” “second,” and the like may be used herein to describe various components, these components are not limited by these terms. These terms are only used to distinguish one element or component from another element or component. Therefore, a first component described below could be termed a second component without departing from the scope and spirit of the present disclosure.

In describing the components of the present specification, terms such as “first,” “second,” “A,” “B,” “(a),” and “(b)” may be used. These terms are merely for the purpose of differentiating one component from another component, and the essence, sequence, order, or number of a corresponding element should not be limited by the terms. When a component is described as “connected,” “coupled,” or “linked” to another component, it may mean not only that the components are directly “connected,” “coupled,” or “linked” but also that they are indirectly “connected,” “coupled,” or “linked” through still another component.

In the present specification, a “display apparatus” may include a narrow-sense display apparatus such as a liquid crystal module (LCM), an organic light-emitting diode (OLED) module, or a quantum dot (QD) module which includes a display panel and a driver for driving the display panel. The display apparatus may include a set electronic device or a set device (or a set apparatus) such as a laptop computer, a television, a computer monitor, an equipment apparatus including an automotive apparatus or other type apparatuses for vehicles, or a mobile electronic device such as a smartphone or an electronic pad, which is a complete product (or a final product) including an LCM, an OLED module, a QD module, or the like.

Therefore, in the present specification, the display apparatus may include a narrow-sense display apparatus itself, such as an LCM, an OLED module, or a QD module and a set device which is an application product or a final consumer device including an LCM, an OLED module, a QD module, or the like.

In some cases, an LCM, an OLED module, or a QD module including a display panel, a driver, and the like may be referred to as a “narrow-sense display apparatus,” and an electronic device which is a final product including an LCM, an OLED module, or a QD module may be referred to as a “set device.” For example, the narrow-sense display apparatus may include a display panel, such as a liquid crystal display (LCD), an OLED, or a QD display panel and a source printed circuit board (PCB) which is a controller for driving the display panel. The set device may further include a set PCB which is a set controller electrically connected to a source PCB to control the entirety of the set device.

As a display panel used in the present aspect, any type of display panel such as an LCD panel, an OLED display panel, or a QD display panel may be used, but the present disclosure is not limited to a specific display panel which is bendable by including a flexible substrate for the OLED display panel and a back play support structure thereunder. A shape or a size of a display panel used in a display apparatus according to aspects of the present specification is not limited.

More specifically, when the display panel is the OLED display panel, the display panel may include a plurality of gate lines, a plurality of data lines, and pixels formed in intersection areas of the gate lines and the data lines. The display panel may include an array including a thin film transistor which is an element for selectively applying a voltage to each pixel, an OLED layer on the array, and an encapsulation substrate or encapsulation layer disposed on the array to cover the OLED layer. The encapsulation layer may protect the thin film transistor and the OLED layer from an external impact and may prevent moisture or oxygen from permeating into the OLED layer. A layer formed on the array may include an inorganic light-emitting layer, for example, a nano-sized material layer, QDs, or the like.

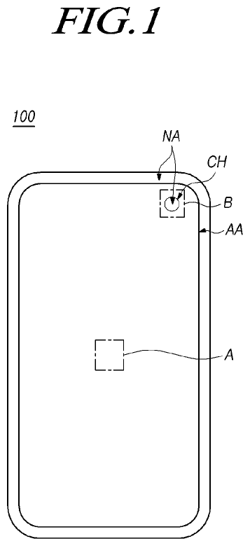

In the present specification, FIG. 1 illustrates an exemplary OLED display panel 100 which may be integrated with components inside display apparatuses.

FIG. 1 is a plan view illustrating the display panel 100 according to an aspect of the present specification. FIG. 1 illustrates the exemplary OLED display panel 100 which may be integrated with components inside the display apparatuses. Referring to FIG. 1, in the OLED display panel 100, a hole CH for a camera and a sensor may be formed inside a display area AA, thereby reducing a bezel area which is a non-display area and maximizing the display area AA. A product designed to maximize a display area AA can be aesthetically preferred by maximizing an immersion level of a user.

The hole CH for the camera and the sensor may be one hole as shown in FIG. 1 but is not limited thereto. The hole CH for the camera and the sensor may be variously formed. For example, one or two holes may be formed inside the display area AA. In this case, a camera may be disposed in a first hole, and a distance sensor or a face recognition sensor and a wide-angle camera may be disposed in a second hole.

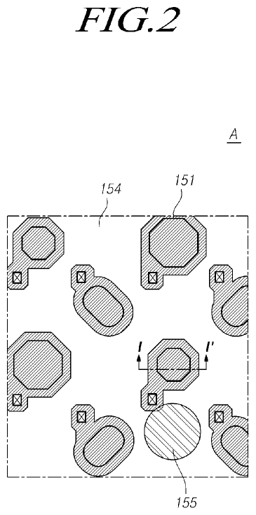

FIG. 2 is an enlarged plan view of area A which is a portion of the display area AA of the display panel 100 of FIG. 1 and illustrates a planar shape of subpixels disposed in the display area AA.

In FIG. 2, a plurality of anodes 151 may be disposed in the display area AA, and a bank 154 may fill an area between the anodes 151. The bank 154 may be disposed to cover an edge of the anode 151 and may serve to define an emission area of the subpixel by allowing only a middle area of the anode 151 to be in contact with an organic light-emitting stack. Spacers 155 may be disposed in a portion of an area in which the bank 154 is disposed. The spacers 155 may be disposed to have a constant density in the entire display panel 100. The spacer 155 may serve to support a mask such that the mask for deposition, which covers or opens an organic layer for each subpixel, is not in direct contact with the display panel 100 when a deposition process is performed to form the organic light-emitting stack. Although FIG. 2 illustrates a PenTile-type planar structure in which the subpixels are arranged in dot shapes, the present disclosure is not limited thereto, and a real-type planar structure may also be used.

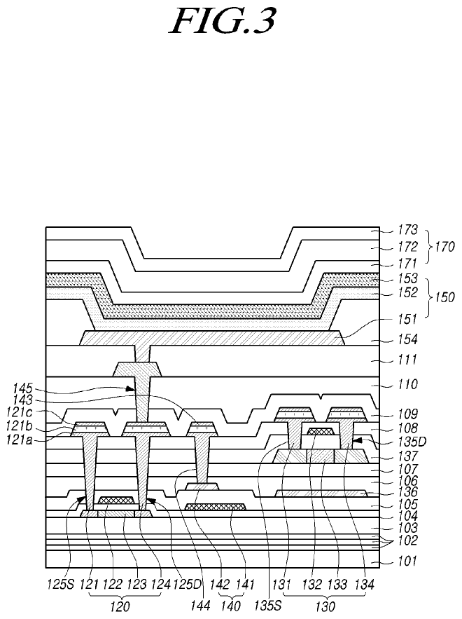

FIG. 3 is a cross-sectional view along line I-I′ of FIG. 2 which illustrates the subpixel.

Referring to FIG. 3, a substrate 101, a multi-buffer layer 102, and a lower buffer layer 103 may be provided, and a first transistor 120 may be disposed on the lower buffer layer 103. A lower gate insulating film 104 may be disposed on a first semiconductor layer 123 constituting the first transistor 120 to insulate the first semiconductor layer 123 from a first gate electrode 122. A first lower interlayer insulating film 105 and a second lower interlayer insulating film 106 may be sequentially disposed on the first gate electrode 122, and an upper buffer layer 107 may be disposed.

The multi-buffer layer 102 may delay diffusion of moisture or oxygen permeating into the substrate 10 and may be formed by alternately stacking silicon nitride (SiNₓ) and silicon oxide (SiOₓ) at least one time.

The lower buffer layer 103 may protect the first semiconductor layer 123 and perform a function of blocking various types of defects introduced from the substrate. The lower buffer layer 103 may be made of a-Si, silicon nitride (SiNₓ), silicon oxide (SiOₓ), or the like.

The first semiconductor layer 123 of the first transistor 120 may be formed as a polycrystalline semiconductor layer and may include a channel region, a source region, and a drain region.

The polycrystalline semiconductor layer may have higher mobility than an amorphous semiconductor layer and an oxide semiconductor layer and thus may have low power consumption and excellent reliability. Due to such advantages, the polycrystalline semiconductor layer may be used for a driving transistor.

The first gate electrode 122 may be disposed on the lower gate insulating film 104 and may be disposed to overlap the first semiconductor layer 123.

A second transistor 130 may be disposed on the upper buffer layer 107, and a light blocking layer 136 may be disposed under an area corresponding to the second transistor 130. Referring to FIG. 3, the light blocking layer 136 may be disposed on the first lower interlayer insulating film 105 in the area corresponding to the second transistor 130, and a second semiconductor layer 133 of the second transistor 130 may be disposed on the second lower interlayer insulating film 106 and the upper buffer layer 107 to overlap the light blocking layer 136. An upper gate insulating film 137 may be disposed on the second semiconductor layer 133 to insulate a second gate electrode 132 from the second semiconductor layer 133, and then an upper interlayer insulating film 108 may be disposed on the second gate electrode 132. The first gate electrode 122 and the second gate electrode 132 may be formed as a single layer or a multi-layer made of at least one selected from among molybdenum (Mo), aluminum (Al), chromium (Cr), gold (Au), titanium (Ti), nickel (Ni), neodymium (Nd), and copper (Cu), or an alloy thereof, but the present disclosure is not limited thereto.

The first and second lower interlayer insulating films 105 and 106 may be formed as inorganic films having a higher hydrogen particle content as compared with the upper interlayer insulating film 108. For example, the first and second lower interlayer insulating films 105 and 106 are made of silicon nitride (SiNₓ) formed through a deposition process using NH₃ gas, and the upper interlayer insulating film 108 may be made of silicon oxide (SiOₓ). Hydrogen particles included in the first and second lower interlayer insulating films 105 and 106 may diffuse into the polycrystalline semiconductor layer during a hydrogenation process to fill pores in the polycrystalline semiconductor layer with hydrogen. Accordingly, the polycrystalline semiconductor layer may be stabilized, thereby preventing degradation in characteristics of the first transistor 120. After an activation and hydrogenation process of the first semiconductor layer 123 of the first transistor 120, the second semiconductor layer 133 of the second transistor 130 may be formed, and in this case, the second semiconductor layer 133 may be made of an oxide semiconductor. Since the second semiconductor layer 133 is not exposed to a high-temperature atmosphere of the activation and hydrogenation process of the first semiconductor layer 123, damage to the second semiconductor layer 133 can be prevented, thereby improving reliability. After the upper interlayer insulating film 108 is disposed, a first source contact hole 125S and a first drain contact hole 125D may be formed to correspond to the source region and the drain region of the first transistor, and a second source contact hole 135S and a second drain contact hole 135d may be respectively formed to correspond to a source region and a drain region of the second transistor 130. Referring to FIG. 3, the first source contact hole 125S and the first drain contact hole 125D may be continuously formed from the upper interlayer insulating film 108 to the lower gate insulating film 104, and the second source contact hole 135S and the second drain contact hole 135D may also be formed in the second transistor 130. A first source electrode 121 and a first drain electrode 124 corresponding to the first transistor 120 and a second source electrode 131 and a second drain electrode 134 corresponding to the second transistor 130 can be formed at the same time, thereby reducing the number of times of processes of forming the source and drain electrodes of each of the first transistor 120 and the second transistor 130.

The first source and drain electrodes 121 and 124 and the second source and drain electrodes 131 and 134 may be formed as a single layer or a multi-layer made of at least one selected from among molybdenum (Mo), aluminum (Al), chromium (Cr), gold (Au), titanium (Ti), nickel (Ni), neodymium (Nd), and copper (Cu), or an alloy thereof, but the present disclosure is not limited thereto. The first source and drain electrodes 121 and 124 and the second source and drain electrodes 131 and 134 may have a three-layered structure. For example, the first source electrode 121 may include a first layer 121a, a second layer 121b, and a third layer 121c, and other source and drain electrodes may have the same structure as the first source electrode 121.

A storage capacitor 140 may be disposed between the first transistor 120 and the second transistor 130. As shown in FIG. 3, the storage capacitor 140 may be formed by overlapping a storage lower electrode 141 and a storage upper electrode 142 with the first lower interlayer insulating film 105 interposed therebetween.

The storage lower electrode 141 may be positioned on the lower gate insulating film 104, formed to be coplanar with the first gate electrode 122, and made of the same material as the first gate electrode 122. The storage upper electrode 142 may be electrically connected to a pixel circuit through a storage supply line 143. The storage upper electrode 142 may be formed to be coplanar with the light blocking layer 136 and made of the same material as the light blocking layer 136. The storage upper electrode 142 is exposed through a storage contact hole 144 passing through the second lower interlayer insulating film 106, the upper buffer layer 107, the upper gate insulating film 137, and the upper interlayer insulating film 108 and is connected to the storage supply line 143. Meanwhile, although the storage upper electrode 142 is spaced apart from the light blocking layer 136 as shown in FIG. 3, the storage upper electrode 142 may be connected to the light blocking layer 136 to be formed integrally with the light blocking layer 136. The storage supply line 143 may be formed to be coplanar with the first source and drain electrodes 121 and 124 and the second source and drain electrodes 131 and 134 and made of the same material as the first source and drain electrodes 121 and 124 and the second source and drain electrodes 131 and 134. Accordingly, the storage supply line 143 may be formed simultaneously with the first source and drain electrodes 121 and 124 and the second source and drain electrodes 131 and 134 through the same mask process.

A protective film 109 may be formed by depositing an inorganic insulating material such as SiNₓ or SiOₓ on an entire surface of the substrate 101 on which the first source and drain electrodes 121 and 124, the second source and drain electrodes 131 and 134, and the storage supply line 143 are formed. A first planarization layer 110 may be formed on the substrate 101 on which the protective film 109 is formed. Specifically, the first planarization layer 110 may be disposed by applying an organic insulating material such as an acrylic resin onto the entire surface of the substrate 101 on which the protective film 109 is formed.

After the protective film 109 and the first planarization layer 110 are be disposed, a contact hole exposing the first source electrode 121 or the first drain electrode 124 of the first transistor 120 may be formed through a photolithography process. A connection electrode 145 made of a material including Mo, Ti, Cu, AlNd, Al, Cr, or an alloy thereof may be disposed in an area of the contact hole exposing the first drain electrode 124.

A second planarization layer 111 may be disposed on the connection electrode 145, and a contact hole exposing the connection electrode 145 may be formed in the second planarization layer 111 to arrange a light-emitting element 150 connected to the first transistor 120.

The light-emitting element 150 may include the anode 151 connected to the first drain electrode 124 of the first transistor 120, at least one organic light-emitting stack 152 formed on the anode 151, and a cathode 153 formed on the organic light-emitting stack 152.

The organic light-emitting stack 152 may include a hole injection layer, a hole transport layer, an emission layer, an electron transport layer, and an electron injection layer, and in a tandem structure in which a plurality of emission layers overlap each other, a charge generation layer may be additionally disposed between the emission layer and the emission layer. In some cases, the emission layer may emit light having different colors for each subpixel. For example, a red emission layer, a green emission layer, and a blue emission layer may be separately formed for each subpixel. However, a common emission layer may be formed to emit white light without color discrimination for each pixel, and a color filter for discriminating colors may be separately provided. The discrimination may be classified into a red-green-blue (RGB) type (real RGB type) and a white OLED (WOLED). Each emission layer may be individually formed, but the injection layer or the transport layer may be provided as a common layer and may be equally disposed for each subpixel.

The anode 151 may be connected to the connection electrode 145 exposed through a contact hole passing through the second planarization layer 111. The anode 151 may be formed in a multi-layered structure including a transparent conductive film and an opaque conductive film having high reflection efficiency. The transparent conductive film is made of a material having a relatively large work function value, such as indium-tin-oxide (ITO) or indium-zinc-oxide (IZO), and the opaque conductive film has a single-layered or multi-layered structure including Al, Ag, Cu, Pb, Mo, Ti, or an alloy thereof. For example, the anode 151 may be formed in a structure in which a transparent conductive film, an opaque conductive film, and a transparent conductive film are sequentially stacked or in a structure in which a transparent conductive film and an opaque conductive film are sequentially stacked. The anode 151 may be disposed in the emission area provided by the bank 154 as well as on the second planarization layer 111 to overlap a pixel circuit area in which the first and second transistors 120 and 130 and the storage capacitor 140 are disposed, thereby increasing an area for emitting light.

The organic light-emitting stack 152 may be formed by stacking the hole transport layer, the organic emission layer, and the electron transport layer on the anode 151 in that order or in the reverse order. In addition, the organic light-emitting stack 152 may further include a charge generation layer and may include first and second light-emitting stacks facing each other with the charge generation layer interposed therebetween.

The bank 154 may be formed to expose the anode 151. The bank 154 may be made of an organic material such as photoacrylic and may include a translucent material, but the present disclosure is not limited thereto. The bank 154 may be made of an opaque material to prevent light interference between the subpixels.

The cathode 153 may be formed on an upper surface of the organic light-emitting stack 152 to face the anode 151 with the organic light-emitting stack 152 interposed therebetween. When the cathode 153 is applied to a top emission type organic light-emitting display apparatus, the cathode 153 may be formed by forming a transparent conductive film to be thin using ITO, IZO, or magnesium-silver (Mg—Ag).

An encapsulation layer 170 for protecting the light-emitting element 150 may be formed on the cathode 153. Since the light-emitting element 150 reacts with external moisture or oxygen due to the characteristics of an organic material of the organic light-emitting stack 152, dark-spots or pixel shrinkage may occur. In order to prevent the dark-spots or pixel shrinkage, the encapsulation layer 170 may be disposed on the cathode 153. The encapsulation layer 170 may include a first inorganic insulating film 171, a foreign material compensation layer 172, and a second inorganic insulating film 173.

A touch unit may be disposed on an upper portion on which the encapsulation layer 170 is formed. The touch unit may include a first touch planarization layer, a touch electrode, and a second touch planarization layer. The first touch planarization layer and the second touch planarization layer may be disposed to eliminate a stepped portion at a point at which the touch electrode is disposed and to allow the touch electrode to be electrically insulated well.

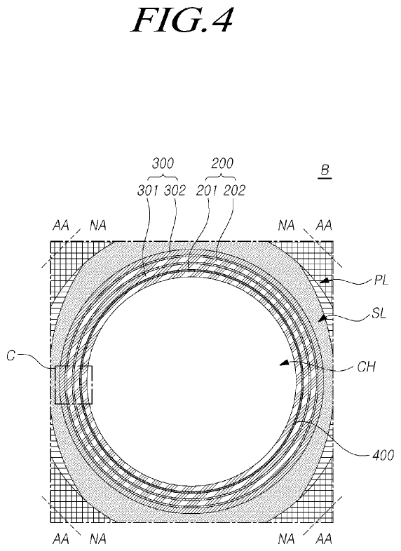

FIG. 4 is an enlarged plan view of area B corresponding to a camera hole area CH of FIG. 1. Referring to FIG. 4, a camera hole CH for arranging a large-sized camera may be formed in a central portion, and a camera module may be disposed therein. The camera hole area CH may include all of a circular camera hole CH and areas, in which a dam structure 300 and a cut-out structure 200 are disposed, near the camera hole CH. The camera hole CH may be removed with a laser in a panel completion operation. A non-display area NA may be positioned between the camera hole area CH and a display area AA, and a high potential power line PL, a gate line SL, and the like may be disposed. The dam structure 300 and the cut-out structure 200 may be disposed around the camera hole CH. Referring to FIG. 4, the dam structure 300 may include a first dam 301 and a second dam 302, and the cut-out structure 200 may include a first cut-out part 201 and a second cut-out part 202. The first dam 301, the first cut-out part 201, the second dam 302, and the second cut-out part 202 may be sequentially disposed from a center of the camera hole CH. In general, a dam structure prevents a foreign material compensation layer 172, which is a part of an encapsulation layer at an outer peripheral portion of a display panel 100, from flowing to an end of the outer peripheral portion of the display panel 100, thereby aiming to maintain a bonding strength between an upper substrate and a lower substrate constituting the display panel 100. In order to prevent the foreign material compensation layer 172 of an encapsulation layer 170 for protecting a light-emitting element 150 from permeating or leaking into the camera hole area CH, the dam structure 300 near the camera hole area CH may also be formed as a plurality of structures such as the first dam 301 and the second dam 302. In the present specification, two dams are provided, but the present disclosure is not limited thereto. An additional dam may be disposed according to an arrangement of a space. Referring to FIG. 4, the first cut-out part 201 and the second cut-out part 202 may be disposed near the first dam 301 and the second dam 302. The first cut-out part 201 and the second cut-out part 202 may be disposed to protect the light-emitting element 150 in the display area from moisture or oxygen that may flow from the camera hole CH. An organic light-emitting stack 152 for the light-emitting element 150 may be deposited on an entire surface of the display panel 100 and may also be uniformly deposited near the camera hole area CH. The organic light-emitting stack 152 may have high reactivity and communicability with respect to moisture and oxygen due to the characteristics of an organic material and thus may deliver moisture and oxygen to the light-emitting element 150 in the display area AA. In order to prevent the delivering of moisture and oxygen, the first and second cut-out parts 201 and 202 may allow the organic light-emitting stack 152 to be partially cut off. In the present specification, two cut-out structures are described, but the present disclosure is not limited thereto.

Referring to FIG. 4, a crack prevention structure 400 may be disposed between the first cut-out part 201 and the first dam 301. The camera hole CH may be formed in a substrate 101 of the display panel 100 to arrange a camera lens. A precision cutting process using a laser may be performed on the substrate 101 to form the camera hole CH, and in this case, the laser may cause microcracks in the substrate 101. The microcracks generated in a cut surface of the camera hole CH may be gradually expanded by stress accumulated as a subsequent module process is performed. Such cracks may be propagated from the non-display area NA to an adjacent display area AA. Due to the expansion of cracks, external oxygen or moisture may reach the light-emitting element 150 in the display area AA through the cracks, and the light-emitting element 150 having organic characteristics may react with oxygen or moisture to cause a pixel shrinkage or dark spot phenomenon in a pixel in a specific area, thereby causing display defects. In order to prevent the expansion of cracks, the crack prevention structure 400 for preventing the expansion of cracks may be disposed near the camera hole CH.

The crack prevention structure 400 may have a structure in which a portion of an inorganic film, in which cracks easily expand, is removed in order to prevent the expansion of cracks generated in the cut surface of the camera hole CH.

All of the first cut-out part 201, the first dam 301, the second cut-out part 202, and the second dam 302 may be disposed in a closed loop shape around the camera hole CH. This is to prevent the penetration of oxygen and moisture at a certain distance from the cut surface of the camera hole CH and to prevent the foreign material compensation layer 172 of the encapsulation layer 170 from overflowing into the camera hole CH.

In addition, the crack prevention structure 400 may also be disposed to have a closed loop shape around the camera hole CH. The crack prevention structure 400 may be disposed to be well combined into a structure in which the first and second cut-out parts 201 and 202 and the first and second dams 301 and 302 are formed, and in order to smoothly perform a crack propagation prevention function, the crack prevention structure 400 should form a perfect closed loop structure without an open portion.

Although a light-emitting element 150 and a pixel circuit are removed from a corresponding area in which the camera hole area CH is disposed, light-emitting elements 150 and pixel circuits disposed at upper, lower, left, and right sides of the camera hole area CH should be electrically connected. To this end, in the non-display area NA near the camera hole area CH, a high potential power line PL, a gate line SL, and the like may be disposed to bypass the camera hole area CH so as to be connected vertically and laterally.

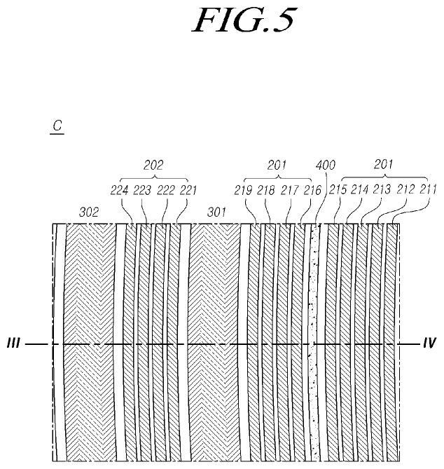

FIG. 5 is an enlarged plan view of area C in the camera hole area CH of FIG. 4. Referring to FIG. 5, the first cut-out part 201 may be disposed between the camera hole CH and the first dam 301, and the second cut-out part 201 may be disposed between the first dam 301 and the second dam 302.

The first cut-out part 201 may include a first structure 211, a second structure 212, a third structure 213, a fourth structure 214, a fifth structure 215, a sixth structure 216, a seventh structure 217, an eighth structure 218, and a ninth structure 219. The second cut-out part 202 may include a tenth structure 221, an eleventh structure 222, a twelfth structure 223, and a thirteenth structure 224.

Although FIG. 5 illustrates that there are nine structures in the first cut-out part 201 and four structures in the second cut-out part 202, the present disclosure is not necessarily limited thereto, and various numbers of cut-out parts may be provided.

Referring to FIG. 5, the crack prevention structure 400 may be formed in an area in which the structures of the first cut-out part 201 are disposed. For example, the crack prevention structure 400 may be disposed between the fifth structure 215 and the sixth structure 216. The crack prevention structure 400 may be disposed between the fifth structure 215 and the sixth structure 216, which are not far from the cut surface of the camera hole CH, thereby preventing cracks, which may be generated in the cut surface, from expanding to the first dam 310.

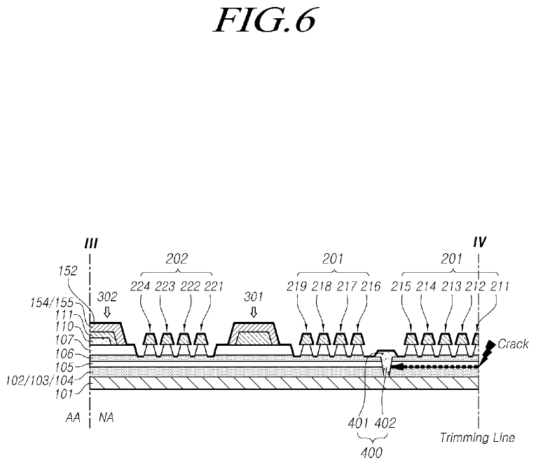

FIG. 6 is a cross-sectional view illustrating a cross section along line III-IV of FIG. 5. Referring to FIG. 6, it can be confirmed that there is the substrate 101 of the display panel 100, and a plurality of inorganic films are disposed on the substrate 101. As the plurality of inorganic films, for example, a multi-buffer layer 102, a lower buffer layer 103, and a lower gate insulating film 104 may be provided, and a first lower interlayer insulating film 105, a second lower interlayer insulating film 106, and an upper buffer layer 107 may be sequentially disposed.

A first planarization layer 110 and a second planarization layer 111 may be disposed on the plurality of inorganic films, and a bank 154 and a spacer 155 may be sequentially disposed. The organic light-emitting stack 152 may be deposited on an entire surface to be disposed on the bank 154 and the spacer 155.

Regarding a cut plane along line it can be seen that the camera hole CH is close to point IV and the display area AA is close to area III. Regarding the cut plane along line in order to cut off the organic light-emitting stack 152 which may become a moisture penetration path, the structures of the first cut-out part 201 may be formed in two stages of an upper structure part and a lower structure part according to the cut surface of the camera hole CH. Specifically, the upper structure part may be disposed such that a cross section thereof has a trapezoidal shape with a positive tapered shape, and the lower structure part may be disposed such that a side surface thereof has a positive tapered shape or a rectangular shape with an almost vertical constant height.

Since a difference in width or breadth occurs between a lower surface of the upper structure part and an upper surface of the lower structure part, which are points at which the upper structure part and the lower structure part meet each other, an undercut structure may be formed on the lower surface of the upper structure part. The lower structure part may be formed of the second lower interlayer insulating film 106 and the upper buffer layer 107, and the upper structure part may be formed of the first planarization layer 110 and the second planarization layer 111.

The upper structure part may be made of an organic material to form the undercut structure. The organic light-emitting stack 152 may be deposited on the entire surface of the display panel 100 using straightness during deposition, but the organic light-emitting stack 152 may be cut off because the organic light-emitting stack 152 cannot be formed on the lower surface of the upper structure part of the cut-out part due to an undercut shape of the upper structure part of the cut-out part.

The first cut-out part 201 and the second cut-out part 202 may include the plurality of structures, thereby preventing oxygen and moisture from permeating through the organic light-emitting stack 152. Although it is described that the first cut-out part 201 has more structures than the second cut-out part 202, the present disclosure is not necessarily limited thereto, and various changes may be applied.

Referring to FIG. 6, the first dam 301 and the second dam 302 are illustrated and are formed in a separation space between the first cut-out part 201 and the second cut-out part 202 and inside the second cut-out part 202, respectively, thereby forming a kind of wall. Although not shown in FIG. 6, the foreign material compensation layer 172 of the encapsulation layer 170 may fill a space between the first dam 301 and the second dam 302. The first dam 301 or the second dam 302 aims to prevent the foreign material compensation layer 172 of the encapsulation layer 170 from overflowing to the camera hole CH and contaminating the camera hole CH.

The crack prevention structure 400 is disposed between the fifth structure 215 and the sixth structure 216 of the first cut-out part 201, thereby preventing cracks, which may be generated in the cut surface of the camera hole CH, from being propagated to the display area AA. The crack prevention structure 400 may be formed by arranging an organic material including the first planarization layer 110 or the second planarization layer 111 in a space in which the multi-buffer layer 102, the lower buffer layer 103, the lower gate insulating film 104, the first lower interlayer insulating film 105, and the second lower interlayer insulating film 106 are removed among the plurality of inorganic films disposed on the substrate 101 of the display panel 100.

In general, the substrate 101 may be perforated using a laser to form the camera hole CH. The laser may radiate in a circular or elliptical shape along a shape of the camera hole CH, and all areas on the substrate including the substrate 101 may be removed through laser radiation.

There may be a difference between the actual camera hole CH and a laser irradiation area, and for example, the laser irradiation area in the camera hole CH may be an area at about 100 μm inside the camera hole CH. Only when there is a difference between the laser irradiation area and the camera hole CH, an insulating layer of the camera hole CH may not be damaged during laser radiation.

As a laser, a picosecond laser or a femtosecond laser may be used, but the present disclosure is not limited thereto. A laser uses light that is induced and emitted by amplifying light generated when energy is applied to a specific material. The laser has the same characteristics as radio waves and has characteristics of monochromatic light and directivity and thus is used for communication, medical, and industrial purposes.

When a laser is used, a pattern can be formed on a desired part, or a specific part can be easily removed. A laser is for forming or removing a pattern using energy, and when laser energy radiates onto a subject, thermal energy melts the subject to form a pattern. As a laser radiation time increases, a thermal effect may occur in which heat is transmitted to the vicinity of a portion at which a pattern is formed. Due to the thermal effect, heat may be accumulated around a laser irradiation area of the subject, and even a surrounding area greater than a set pattern may be burned or deformed by the heat.

Due to such characteristics of a laser, when an area onto which the laser radiates overlaps an insulating film or is adjacent to the insulating film, thermal energy of the laser may also cause deformation of the insulating film. Cracks may be generated due to the deformation of the insulating film, and the cracks may be propagated through the insulating film to cause delamination, which may cause penetration of moisture and oxygen. For example, in order to prevent deformation or delamination of insulating films such as the multi-buffer layer 102, the lower buffer layer 103, the first lower interlayer insulating film 105, the second lower interlayer insulating film 106, the upper buffer layer 107, and the upper interlayer insulating film 108, all the insulating films may be removed at a distance of about 100 μm from a laser radiation position.

When all the insulating films are removed, side surfaces of the substrate 101 and the insulating films may be exposed, but a first inorganic insulating film 171 and a second inorganic insulating film 173 of the encapsulation layer 170 may cover the side surfaces.

Cracks generated, when the substrate 101 is cut using a laser, have characteristics that are easily propagated through an inorganic film. Moisture and oxygen have characteristics that are delivered by reacting with the organic light-emitting stack 152, but cracks may be easily propagated through non-flexible and hard inorganic films. The crack prevention structure 400 may be designed based on such crack propagation characteristics.

An exposed area of the substrate 101 may be formed by removing the multi-buffer layer 102, the lower buffer layer 103, the lower gate insulating film 104, the first lower interlayer insulating film 105, and the second lower interlayer insulating film 106 among the plurality of inorganic films disposed on the substrate 101, and then, the first planarization layer 110 or the second planarization layer 111 may be disposed to cover the exposed area of the substrate and side exposed portions of the plurality of inorganic films.

The plurality of inorganic films may be removed to expose the substrate 101, and the crack prevention structure 400 made of an organic material may cover an area in which the plurality of inorganic films are removed so that cracks generated in the camera hole CH may be absorbed by the crack prevention structure 400.

The crack prevention structure 400 may be divided into an upper structure part 401 and a lower structure part 402. The upper structure part 401 may have a width greater than that of the structures constituting the first cut-out part 201 or the second cut-out part 202, and the lower structure part 402 may have a width less than that of the first cut-out part 201 or the second cut-out part 202.

Referring to FIG. 6, as for a shape of the crack prevention structure 400, the lower structure part 402 may have an inverted trapezoidal shape in which an inorganic film removal portion of the multi-buffer layer 102 is the narrowest and inorganic film removal portions are widened in the order from the lower buffer layer 103, the lower gate insulating film 104, the first lower interlayer insulating film 105, and the second lower interlayer insulating film 106.

Since there is a high probability that cracks are generated in the first lower interlayer insulating film 105 and the second lower interlayer insulating film 106 with which a laser first comes into contact in the camera hole CH of the display panel 100, the lower structure part 402 of the crack prevention structure 400 may be formed such that the first lower interlayer insulating film 105 and the second lower interlayer insulating film 106 may be widely removed.

The upper structure part 401 of the crack prevention structure 400 may sufficiently cover the lower structure part 402 of the crack prevention structure 400 so that removed portions of the plurality of inorganic films on the substrate 101 may not be exposed.

Accordingly, the upper structure part 401 of the crack prevention structure 400 may have a trapezoidal shape with a wide lower portion and a narrow upper portion. Referring to FIG. 6, when viewed in a cross-sectional structure, the crack prevention structure 400 may be divided into the upper structure part 401 and the lower structure part 402, and when viewed in a planar structure, the crack prevention structure 400 forms an annular closed loop spaced a certain distance apart from the camera hole CH.

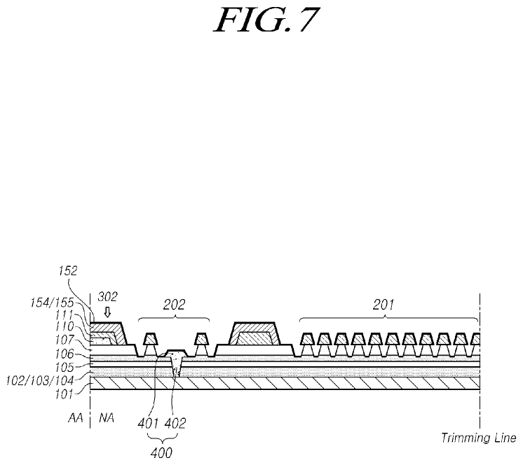

FIG. 7 is a cross-sectional view illustrating an arrangement of a crack prevention structure according to another aspect of the present disclosure. Referring to FIG. 7, a crack prevention structure 400 may be formed in an area in which a second cut-out part 202 is disposed. Unlike the aspect of FIG. 6, a design structure of another aspect is dedicated to preventing penetration of oxygen and moisture through an organic light-emitting stack 152 by arranging the crack prevention structure 400 close to a display area AA, and continuously arranging a first cut-out part 201 near the camera hole CH. In addition, as cracks starting from the camera hole CH are propagated to a side surface, the strength of the cracks may be gradually decreased, thereby serving to prevent the cracks at a front end of the display area AA. Referring to FIG. 7, like the aspect of FIG. 6, in the crack prevention structure 400, an upper structure part 401 and a lower structure part 402 may be disposed, and the upper structure part 401 may have a trapezoidal shape, and the lower structure part 402 may have an inverted trapezoidal shape.

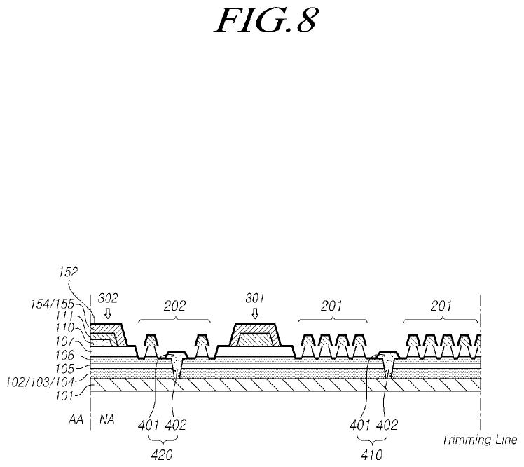

FIG. 8 is a cross-sectional view illustrating an arrangement of a crack prevention structure 400 according to still another aspect of the present disclosure.

Referring to FIG. 8, the crack prevention structure 400 is disposed in each of a first cut-out part 201 and a second cut-out part 202, thereby serving to doubly block cracks, which may be generated in a camera hole CH, from approaching a display area AA.

As in the other aspects, the crack prevention structure 400 of FIG. 8 may have a structure in which portions of a plurality of inorganic films on a substrate 101 are removed to form an upper structure part 401 and a lower structure part 402.

A first crack prevention structure 410 may be disposed in the first cut-out part 201, and a second crack prevention structure 420 may be disposed in the second cut-out part 202. When the plurality of crack prevention structures are disposed as described above, there is an advantage in that cracks passing through the first crack prevention structure 410 can be prevented from being propagated to the display area AA through the second crack prevention structure 420.

When it is determined that penetration of moisture and oxygen into the display area AA through an organic light-emitting stack 152 can be sufficiently prevented, a partial area of each of the first cut-out part 201 and the second cut-out part 202 may be converted into an area in which the crack prevention structure 400 is disposed.

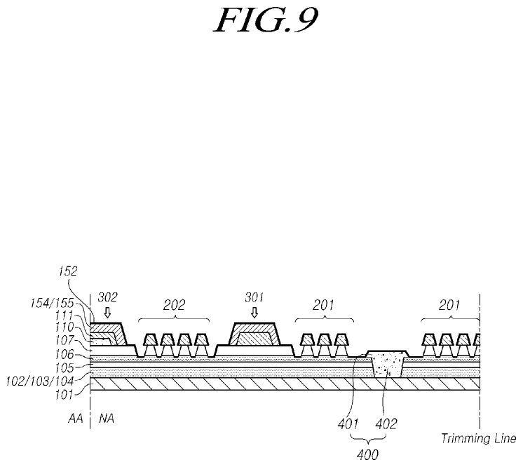

FIG. 9 is a cross-sectional view illustrating an arrangement of a crack prevention structure 400 according to yet another aspect of the present disclosure.

Referring to FIG. 9, the crack prevention structure 400 having a size greater than that of the crack prevention structure 400 of FIG. 6 may be disposed in a first cut-out part 201. For example, the crack prevention structure 400 of FIG. 9 may have a width that is about twice a width of the crack prevention structure 400 of other aspects.

When the crack prevention structure 400 of other aspects may have a width of about 20 μm, the crack prevention structure 400 of FIG. 9 may have a width of about 40 μm.

When cracks having high energy are generated in a camera hole CH by a stronger impact, a phenomenon may occur in which the cracks pass though the crack prevention structure 400 of the existing aspect to continuously propagate. In order to prevent the phenomenon, an area, in which a plurality of inorganic films on a substrate 101 are removed, may be more than doubled to expand a lower structure part 402 of the crack prevention structure 400.

Accordingly, even when cracks having high energy are generated, it is possible to prevent the cracks from propagating to the display area AA. The crack prevention structure 400 of FIG. 9 may have a width that is two or three times that of a structure of the first cut-out part 201.

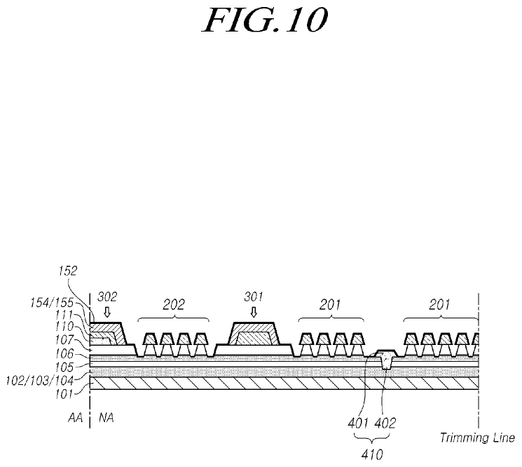

FIG. 10 is a cross-sectional view illustrating an arrangement of a crack prevention structure 400 according to yet another aspect of the present disclosure.

Referring to FIG. 10, the crack prevention structure 400 may have a shape in which only a lower gate insulating film 104 is removed so that an upper surface of a lower buffer layer 103 is in contact with a lower structure part 402 of the crack prevention structure 400.

There is a high probability that cracks are generated in a first lower interlayer insulating film 105 and a second lower interlayer insulating film 106 with which a laser first comes into contact in a process of forming a camera hole CH.

When, in addition to a first lower interlayer insulating film 105 and a second lower interlayer insulating film 106 having a high probability of the generation of cracks among a plurality of inorganic films, a lower gate insulating film 104 is further removed to form the lower structure part 402 of the crack prevention structure 400, there are advantages in that crack propagation with a high probability can be prevented and also, a structure can be easily formed because there are a relatively small number of inorganic films to be removed.

In the aspect of FIG. 10, it is possible to minimize quality problems that may occur in a process of removing a structure of a first cut-out part 201 and the plurality of inorganic insulating films.

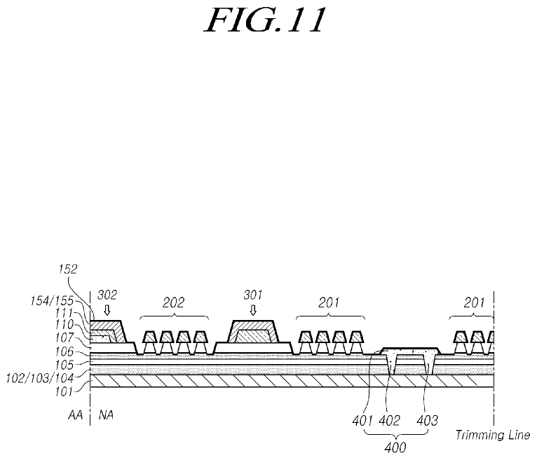

FIG. 11 is a cross-sectional view illustrating an arrangement of a crack prevention structure 400 according to yet another aspect of the present disclosure.

Referring to FIG. 11, the crack prevention structure 400 of FIG. 11 may have a shape in which an area in which a substrate 101 is exposed is minimized to leave a portion of a plurality of inorganic films and remove a portion of the plurality of inorganic films. For example, the plurality of inorganic films may be removed in an area close to a camera hole CH to expose the substrate 101, and the plurality of inorganic films may be removed again to remove the substrate 101 in an area spaced a certain distance apart from the area close to the camera hole CH.

A first lower structure part 402 and a second lower structure part 403 of the crack prevention structure 400 may be disposed in the areas to fill the areas in which the plurality of inorganic insulating films are removed, and an upper structure part 401 may be disposed to connect the two areas.

Through such a structure, the plurality of inorganic insulating films remaining inside the crack prevention structure 400 may form one wall to prevent crack expansion.

In the propagation of cracks, when the cracks reach the crack prevention structure 400, the cracks should meet a second lower structure part 403 to pass through an interface and should cross a remaining inorganic film wall again to pass through the first lower structure part 402, and thus, there may be an advantage in preventing the propagation of the cracks.

Referring to FIG. 11, a cross-sectional shape of the crack prevention structure 400 is similar to that of a root of a tooth, and thus, thereby improving a bonding strength or durability between a display panel 100 and the crack prevention structure 400.

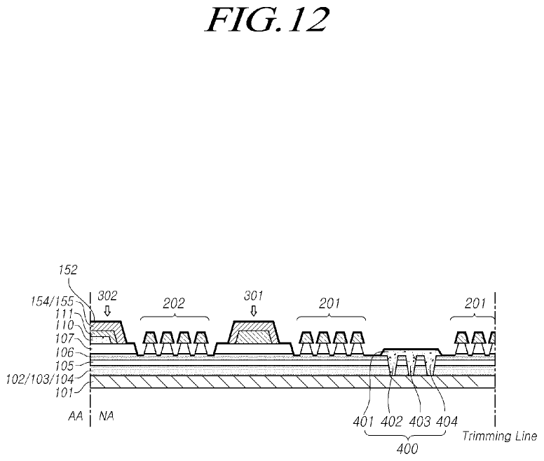

FIG. 12 is a cross-sectional view illustrating an arrangement of a crack prevention structure 400 according to yet another aspect of the present disclosure.

Referring to FIG. 12, a structure of the crack prevention structure 400 according to the aspect of FIG. 11 may be modified to form two walls which are formed of a plurality of inorganic films, and an area in which portions of the plurality of inorganic layers are removed may be formed to form three lower structure parts.

As in the aspect of FIG. 11, the present aspect is an aspect in which the plurality of inorganic films and a third lower structure part 404 constituting the crack prevention structure 400 are added, and as compared with the aspect of FIG. 11, the crack prevention structure 400 has a structure in which one inorganic film wall and one organic film wall are further formed. Thus, the crack prevention structure 400 can be more effective in preventing the propagation of cracks.

When cracks are propagated to reach the crack prevention structure 400, the cracks should pass through three lower structure parts, for example, the third lower structure part 404, a second lower structure part 403, a first lower structure part 402, and an inorganic film wall disposed between the lower structure parts, it is possible to reduce a possibility of crack propagation.

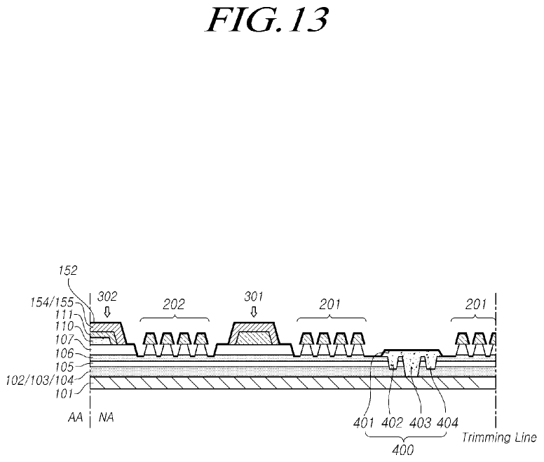

FIG. 13 is a cross-sectional view illustrating an arrangement of a crack prevention structure 400 according to yet another aspect of the present disclosure.

Referring to FIG. 13, the crack prevention structure 400 of FIG. 13 may be formed to have a structure in which a structure of the crack prevention structure 400 of FIG. 12 is changed to remove a plurality of inorganic films up to a lower gate insulating film 104 at a point adjacent to a camera hole CH and a point adjacent to a display area AA and remove the plurality of inorganic films up to an upper portion of a substrate 101 between the two points.

When the crack prevention structure 400 is disposed in areas of the removed inorganic layers, a first lower structure part 402 and a third lower structure part 404 may be disposed in areas in which the inorganic layers are removed up to the lower gate insulating film 104, and a second lower structure part 403 may be disposed between the first lower structure part 402 and the third lower structure part 404.

The first lower structure part 402 and the third lower structure part 404 of the crack prevention structure 400 can prevent crack propagation from a first lower interlayer insulating film 105 or a second lower interlayer insulating film 106 having a high possibility of the generation of cracks, and also, a process of removing the inorganic films up to an upper surface of the substrate 101 can be omitted.

The second lower structure part 403 of the crack prevention structure 400 may prevent cracks from propagating to a multi-buffer layer 102 or a lower buffer layer 103.

In the present aspect, the lower structure parts of the crack prevention structure 400 are differently disposed, thereby preventing cracks propagating through various paths, and at the same time, the crack prevention structure 400 is allowed to have a sufficient size, thereby preventing the propagation of cracks with various strengths.

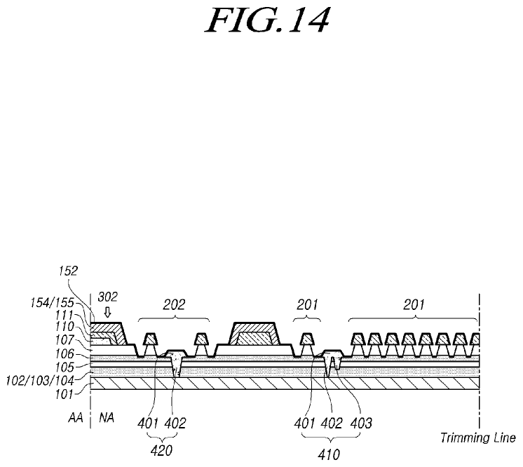

FIG. 14 is a cross-sectional view illustrating an arrangement of a crack prevention structure 400 according to yet another aspect of the present disclosure.

Referring to FIG. 14, as in that shown in FIG. 8, a first crack prevention structure 410 and a second crack prevention structure 420 are disposed in a first cut-out part 201 and a second cut-out part 202. The present aspect is different from the aspect of FIG. 8 in that the first crack prevention structure 410 disposed in the first cut-out part 201 may include a plurality of lower structure parts, for example, a first lower structure part 402 and a second lower structure part 403.

Since the first crack prevention structure 410 is further disposed adjacent to a camera hole CH in addition to the second crack prevention structure 420 adjacent to a display area AA, it is possible to prevent cracks with various paths and high strength.

In addition, referring to FIG. 14, the first crack prevention structure 410 may be disposed adjacent to a first dam 301 so that structures of the first cut-out part 201 can be consecutively disposed near the camera hole CH. This may be a method for more effectively responding to the penetration of oxygen and moisture through an organic light-emitting stack 152 from the external camera hole CH and may be achieved by consecutively arranging six or eight or more structures of the first cut-out part 201.

The structures of the first cut-out part 201 are densely disposed to prevent the penetration of oxygen and moisture, and at the same time, the first crack prevention structure 410 is allowed to include the first lower structure part 402 and the second lower structure part 403, thereby preventing cracks from propagating to the display area AA.

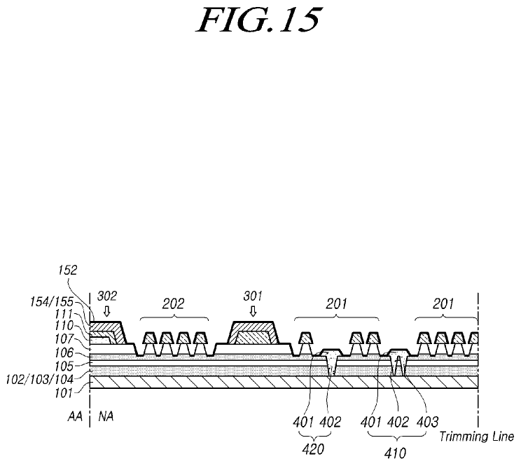

FIG. 15 is a cross-sectional view illustrating an arrangement of a crack prevention structure 400 according to yet another aspect of the present disclosure. Referring to FIG. 15, a first crack prevention structure 410 and a second crack prevention structure 420 are disposed in a first cut-out part 201, thereby serving to completely block cracks that may occur in a camera hole CH.

The first crack prevention structure 410 and the second crack prevention structure 420 are sequentially disposed in the first cut-out part 201 that is as far away from a display area AA as possible and is closest to the camera hole CH, thereby minimizing an influence on the display area AA.

The first crack prevention structure 410 may be allowed to include two lower structure parts as in the aspect of FIG. 11 and may be disposed such that it is difficult for cracks generated in the camera hole CH to pass through interfaces of the first lower structure part 402 and the second lower structure part 403.

Although a display apparatus according to an aspect of the present specification has been described based on the fact that a substrate corresponding to a camera hole CH is removed by a laser, the present disclosure is not necessarily limited thereto, and a component of the substrate or only a portion of the substrate may be removed.

A display apparatus according to an aspect of the present specification may include an LCD, a field emission display device (FED), an OLED display device, and a QD display device.

The display apparatus according to the aspect of the present specification may include a set electronic device/apparatus or a set device (or a set apparatus) such as a laptop computer, a television, a computer monitor, an equipment display apparatus including an automotive display apparatus or another type apparatuses for vehicles, or a mobile electronic device/apparatus such as a smartphone or an electronic pad, which is a complete product (or a final product) including an LCM, an OLED module, or the like.

A display apparatus according to an aspect of the present specification may be described as follows.

A display apparatus according to an aspect of the present specification may include a substrate including a display area, a camera hole, and a non-display area disposed between the display area and the camera hole, a light-emitting element disposed in the display area, one or more cut-out parts and at least one dam disposed in the non-display area, a plurality of insulating films disposed on the substrate and disposed under the light-emitting element, the cut-out part, and the dam, and one or more crack prevention structures disposed between the at least one dam and the camera hole.

In the display apparatus according to the aspect of the present specification, each crack prevention structure may include an upper structure part and one or more lower structure parts.

In the display apparatus according to the aspect of the present specification, the plurality of insulating films may include a multi-buffer layer and a lower buffer layer.

The display apparatus according to the aspect of the present specification may include areas in which the substrate is exposed by removing the multi-buffer layer and the lower buffer layer in the non-display area.

In the display apparatus according to the aspect of the present specification, the one or more lower structure parts of the crack prevention structure may be disposed in the areas in which the substrate is exposed. The upper structure part of the crack prevention structure may be disposed on the one or more lower structure parts.

In other words, in the display apparatus according to the aspect of the present specification, at least one of the multi-buffer layer and the lower buffer layer may include one or more openings in the non-display area.

The one or more lower structure parts of the crack prevention structure may be positioned inside the openings. The upper structure part of the crack prevention structure may be disposed on the one or more lower structure parts.

In the display apparatus according to the aspect of the present specification, the plurality of insulating films may include a gate insulating film and an interlayer insulating film.

In the display apparatus according to the aspect of the present specification, the one or more lower structure parts of the crack prevention structure may be disposed in areas in which the gate insulating film and the interlayer insulating film are removed in the non-display area. The upper structure part of the crack prevention structure may be disposed on the one or more lower structure parts.

In other words, in the display apparatus according to the aspect of the present specification, at least one of the gate insulating film and the interlayer insulating film may include one or more openings in the non-display area.

The one or more lower structure parts of the crack prevention structure may be positioned inside the openings. The upper structure part of the crack prevention structure may be disposed on the one or more lower structure parts.

In the display apparatus according to the aspect of the present specification, a first cut-out part of the one or more cut-out parts may be disposed between the at least one dam and the camera hole.

In the display apparatus according to the aspect of the present specification, a second cut-out part of the one or more cut-out parts may be disposed between the at least one dam and the display area.

In the display apparatus according to the aspect of the present specification, the crack prevention structure may be disposed in the first cut-out part.

In the display apparatus according to the aspect of the present specification, the crack prevention structure may be disposed in the second cut-out part.

A display apparatus according to an aspect of the present specification may include a substrate including a non-display area disposed between a camera hole and a display area, a plurality of inorganic insulating films disposed in the display area and the non-display area, an organic light-emitting stack disposed on the plurality of inorganic insulating films to correspond to the display area, one or more cut-out parts and at least one dam disposed on the plurality of inorganic insulating films to correspond to the non-display area, and a crack prevention structure disposed in the one or more cut-out parts.

In the display apparatus according to the aspect of the present specification, the crack prevention structure may include an upper structure part and one or more lower structure parts.

In the display apparatus according to the aspect of the present specification, the plurality of inorganic insulating films may include a multi-buffer layer and a lower buffer layer.

The display apparatus according to the aspect of the present specification may include areas in which the substrate is exposed by removing the multi-buffer layer and the lower buffer layer in the non-display area.

In the display apparatus according to the aspect of the present specification, the one or more lower structure parts of the crack prevention structure may be disposed in the areas in which the substrate is exposed. The upper structure part of the crack prevention structure may be disposed on the one or more lower structure parts.

In other words, in the display apparatus according to the aspect of the present specification, at least one of the multi-buffer layer and the lower buffer layer may include one or more openings in the non-display area.

The one or more lower structure parts of the crack prevention structure may be positioned inside the openings. The upper structure part of the crack prevention structure may be disposed on the one or more lower structure parts.

In the display apparatus according to the aspect of the present specification, the plurality of inorganic insulating films may include a gate insulating film and an interlayer insulating film.

In the display apparatus according to the aspect of the present specification, the one or more lower structure parts of the crack prevention structure may be disposed in areas in which the gate insulating film and the interlayer insulating film are removed in the non-display area. The upper structure part of the crack prevention structure may be disposed on the one or more lower structure parts.

In other words, in the display apparatus according to the aspect of the present specification, at least one of the gate insulating film and the interlayer insulating film may include one or more openings in the non-display area.

The one or more lower structure parts of the crack prevention structure may be positioned inside the openings. The upper structure part of the crack prevention structure may be disposed on the one or more lower structure parts.

In the display apparatus according to the aspect of the present specification, a first cut-out part of the one or more cut-out parts may be disposed between the at least one dam and the camera hole.

In the display apparatus according to the aspect of the present specification, a second cut-out part of the one or more cut-out parts may be disposed between the at least one dam and the display area.

In the display apparatus according to the aspect of the present specification, the crack prevention structure may be disposed in the first cut-out part.

The features, structures, and effects described above in the examples of the present application are included in at least one example of the present application, but the present disclosure is not limited to only one example. Furthermore, the features, structures, and effect described in at least one example of the present application may be implemented through combinations or modifications of other examples by those skilled in the art to which the present application belongs. Therefore, content associated with the combinations and modifications should be construed as being within the scope of the present application.

It will be apparent to those skilled in the art to which the present application belongs that the present application is not limited to the above-described aspects and the accompanying drawings and various substitutions, modifications, and variations can be made without departing from the spirit or scope of the present application. Thus, the scope of the present application is defined by the claims described below, and the present application should be construed to cover all modifications or variations induced from the meaning and scope of the appended claims and their equivalents.

What is claimed is:

1. A display apparatus comprising:
a substrate including a display area, a camera hole, and a non-display area between the display area and the camera hole;
a light-emitting element disposed in the display area;
one or more cut-out parts and at least one dam disposed in the non-display area;
a plurality of insulating films disposed on the substrate and disposed under the light-emitting element, the cut-out parts, and the dam; and
a crack prevention structure disposed between the at least one dam and the camera hole.

2. The display apparatus of claim 1, wherein the crack prevention structure comprises an upper structure part and one or more lower structure parts.

3. The display apparatus of claim 2, wherein the plurality of insulating films comprise a multi-buffer layer and a lower buffer layer.

4. The display apparatus of claim 3, wherein the substrate has an area exposed by removing the multi-buffer layer and the lower buffer layer in the non-display area.

5. The display apparatus of claim 4, wherein the one or more lower structure parts of the crack prevention structure are disposed in the area in which the substrate is exposed; and
the upper structure part of the crack prevention structure is disposed on the one or more lower structure parts.

6. The display apparatus of claim 2, wherein the plurality of insulating films comprise a gate insulating film and an interlayer insulating film.

7. The display apparatus of claim 6, wherein the one or more lower structure parts of the crack prevention structure are disposed in an area in which the gate insulating film and the interlayer insulating film are removed in the non-display area; and
the upper structure part of the crack prevention structure is disposed on the one or more lower structure parts.

8. The display apparatus of claim 1, wherein the one or more cut-out parts comprise:
a first cut-out part of the one or more cut-out parts is disposed between the at least one dam and the camera hole; and
a second cut-out part of the one or more cut-out parts is disposed between the at least one dam and the display area.

9. The display apparatus of claim 8, wherein the crack prevention structure is disposed in the first cut-out part.

10. The display apparatus of claim 8, wherein the crack prevention structure is disposed in the second cut-out part.

11. A display apparatus comprising:
a substrate comprising a non-display area disposed between a camera hole and a display area;
a plurality of inorganic insulating films disposed in the display area and the non-display area;
an organic light-emitting stack disposed on the plurality of inorganic insulating films to correspond to the display area;
one or more cut-out parts and at least one dam disposed on the plurality of inorganic insulating films to correspond to the non-display area; and
a crack prevention structure disposed in the one or more cut-out parts.

12. The display apparatus of claim 11, wherein the crack prevention structure comprises an upper structure part and one or more lower structure parts.

13. The display apparatus of claim 12, wherein the plurality of inorganic insulating films comprise a multi-buffer layer and a lower buffer layer.

14. The display apparatus of claim 13, wherein the substrate has an area exposed by removing the multi-buffer layer and the lower buffer layer in the non-display area.

15. The display apparatus of claim 14, wherein the one or more lower structure parts of the crack prevention structure are disposed in the area in which the substrate is exposed; and
the upper structure part of the crack prevention structure is disposed on the one or more lower structure parts.

16. The display apparatus of claim 12, wherein the plurality of inorganic insulating films comprise a gate insulating film and an interlayer insulating film.

17. The display apparatus of claim 16, wherein the one or more lower structure parts of the crack prevention structure are disposed in an area in which the gate insulating film and the interlayer insulating film are removed in the non-display area; and
the upper structure part of the crack prevention structure is disposed on the one or more lower structure parts.

18. The display apparatus of claim 11, wherein the one or more cut-out parts comprise:
a first cut-out part of the one or more cut-out parts is disposed between the at least one dam and the camera hole; and
a second cut-out part of the one or more cut-out parts is disposed between the at least one dam and the display area.

19. The display apparatus of claim 18, wherein the crack prevention structure is disposed in the first cut-out part.
